(19) United States
(12) Patent Application Publication
(10) Pub. No.: US 2026/0360660 A1
(43) Pub. Date: Nov. 12, 2026

(54) Textured Shields for Rotatable Platen

(71) Applicant: Applied Materials, Inc., Santa Clara, CA (US)

(72) Inventors: James Alan Pixley, Gloucester, MA (US); Gregory E. Stratoti, Haverhill, MA (US); Bon-Woong Koo, Andover, MA (US); Alexandre Likhanskii, Malden, MA (US)

(73) Assignee: Applied Materials, Inc., Santa Clara, CA (US)

(21) Appl. No.: 19/657,384

(22) Filed: Apr. 24, 2026

Related U.S. Application Data
(60) Provisional application No. 63/802,125, filed on May 8, 2025.

(51) Int. Cl. H01J 37/20; H01J 37/30; H01J 37/317

(52) U.S. Cl. CPC H01J 37/20; H01J 37/3002; H01J 37/3171; H01J 2237/2007; H01J 2237/20214

(57) ABSTRACT

The present disclosure relates to rotary platens used in ion implanters, where such platens having surfaces adjacent to and/or in the path of the ion beam. Such surfaces will be prone to deposition and the present invention addresses problems associated with delamination of deposited material. A rotatable platen is provided that includes a plurality of textured surfaces, which in some embodiments include serrations.

### CROSS-REFERENCE TO RELATED APPLICATIONS

This is a non-provisional application of pending U.S. provisional patent application serial number 63/802,125, filed May 8, 2025, the entirety of which application is incorporated by reference herein.

### FIELD OF THE DISCLOSURE

The present invention relates to components in ion implanters having surfaces adjacent to the path of the ion beam through the ion implanter. Such surfaces will be prone to deposition and the present invention addresses problems associated with delamination of deposited material.

### Background of the Disclosure

Ion implanters are used in the manufacture of semi-conductor devices and other materials. In such ion implanters, semiconductor wafers or other substrates are modified by implanting atoms of a desired species into the body of the substrate, for example to form regions of varying conductivity.

Ion implanters are well known and generally conform to a common design as follows. An ion source generally comprises an arc chamber in which a hot plasma is generated. The plasma will contain ions of a desired species to be implanted. An extraction lens assembly produces an electric field that extracts ions from the ion source and forms a mixed beam of ions. Only ions of a particular species are usually required for implantation in a substrate, for example a particular dopant for implantation in a semiconductor wafer. The required ions are selected from the mixed ion beam that emerges from the ion source by using a mass analyzing magnet in association with a mass resulting slit. By setting appropriate operational parameters on the mass analyzing magnet and the ion optics associated therewith, an ion beam containing almost exclusively the required ion species emerges from the mass resolving slit.

This ion beam is transported to a process chamber where the ion beam is incident on a substrate held in place in the ion beam path by a substrate holder. Accordingly, ions are produced in an ion source and transported to a process chamber along an ion beam path.

In addition to the above-described operations, further procedures may be performed. For example, it is common to perform low-energy implants, but this has an associated problem in that a slow-moving ion beam is susceptible to space charge blow-up. Accordingly, ions are often accelerated as they are extracted from the ion source to travel along the ion beam path at high energy. The ion beams then pass through a deceleration lens assembly prior to implantation in the substrate. In addition, other ion optics may be included along the ion beam path to steer and shape the ion beam and to prevent loss of current from the ion beam. Other components such as a plasma flood system may be placed along the ion beam path.

During normal operation of an ion implanter, material is produced that gets deposited on various components within the ion implanter. This material arises from a number of sources. For example, some material may be lost from the ion beam, such as the species to be implanted or contaminants entrained within the ion beam. Another major source of deposition material is the photoresist cover that is provided on substrates be implanted. The heat generated by the ion beam striking the substrate causes outgassing of carbon, hydrogen and hydrocarbons that may then deposit on surfaces. Another source of contaminants is material from ion implanter components that surround the ion beam path. If the ion beam strikes such components, material may be sputtered from that surface only to adhere to another surface within the ion implanter. As the surfaces surrounding the ion beam path are typically made from graphite, carbon is a major component in the deposited material.

Clearly, surfaces adjacent to the ion beam are most prone to receiving deposits. As the amount of material deposited accumulates, the chances of the deposits delaminating to form flakes or particles increases. These flakes or particles frequently detach from their host surface and may become entrained in the ion beam. Consequently, the flakes or particles may reach the substrate where they represent a contaminant and may damage the semiconductor material.

Depending on the species, energy, and incident angle, the ion beam could form continuous thick deposits on the interior surfaces exposed to ion beam path, or sputter away materials which preferentially accumulate in certain area. Such deposited films are under thermal and mechanical stress due to beam strike and/or thermal cycle and are thus prone to crack and fracture causing particles, defects, and yield loss. With the shrinking of device sizes and requirement for higher device yield, it is important to control and reduce the source of particle defects from the ion beam and beamline components interaction. For example, highly stressed films can be formed on surfaces of the ion implanter that the ion beam directly strikes. Hard materials originating from these films, when they detach, have enough energy to travel at the speed of ≥10 m/sec. When these materials hit the substrate, they can damage semiconductor device structures resulting in device yield loss.

Known approaches to prevent such damage include (1) performing time consuming tool preventive maintenance after processing 1,000 to 10,000 substrates, and (2) operating the tool in a mixed beam mode - cycling various ion implant species and energies - to alter the deposited film property. As will be understood, such approaches can be undesirably inefficient and time consuming, resulting in the overall productivity loss.

In a further example, where the affected surfaces are associated with a substrate platen, such surfaces can be covered with graphite or can be covered with an Aluminum-containing foam. Such arrangements can be less effective, however, when the substrate platen is a rotatable platen, (i.e., a platen capable of adjusting the angle of a substrate with respect to an incoming ion beam), and where specific implant applications require a high tilt angle with respect to the ion beam. Such high tilt applications can expose surfaces of the platen to direct ion beam strikes or energetic secondary materials, reducing or eliminating the effectiveness of the graphite and/or Aluminum-containing form coverings.

Accordingly, improved approaches for mitigation of formation of hard film materials on surfaces of an ion implanter, in particular rotatable platen surfaces, are needed.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

The disclosure is related to reducing particle defects on substrates during implant process by eliminating particle sources due to ion beam and beamline components interaction (by direct deposition and/or accumulation of re-sputtered materials). As will be understood, highly stressed films formed during the ion implant process can physically damage semiconductor device structures. The disclosure includes textured surfaces that may significantly reduce defect formation.

In one example embodiment, a rotatable platen is provided with serrations on surfaces that will be exposed to the ion beam across the full range of motion (i.e. tilt) of the platen. Specific texture directions provide maximum absorption of sputtered materials and redirection of the energetic re-sputtered materials away from critical components, thus controlling particles and metal contamination. In example cases, depositions will be collected in and/or sputtered away from the valleys of the serrations, preventing the deposits from migrating toward the substrate held by the platen. The disclosed arrangements are expected to significantly reduce the amount of the ion beam induced deposits that form on platen surfaces across all substrate tilt conditions, and to significantly reduce damage (sputtering, contamination) from energetic sputtered/recoiled atoms produced during implant operations. Such reductions can extend dedicated (or high %) implant processes without performing frequent tool preventive maintenance. In addition, the disclosed arrangements provide protection to the rotatable platen components from direct ion beam impact as well as impacts from energetic secondary particles.

In some embodiments, surface texturing can include texture orientations to maximize absorption of sputtered materials and to redirect energetic re-sputtered materials away from critical components in the process chamber. Although the design is disclosed for use in the context of a rotatable platen, it will be appreciated that the disclosed concepts can be applied to other implant tools and/or processes.

A platen is disclosed for use in an ion implanter. The platen may include a base portion, a platen portion rotatably coupled to the base portion, a front cover coupled to a front of the platen portion, first and second side covers coupled to first and second stationary shoulder portions of the base portion, and a nose cover coupled to a front portion of the base portion. In some non-limiting example embodiments, the first and second side covers, and the nose cover, each comprise a surface texturing.

In some non-limiting example embodiments, the surface texturing comprises a plurality of serrations. In some non-limiting example embodiments, the surface texturing of the front cover can include a plurality of serrations, where the peaks and valleys of the serrations are oriented perpendicular to the central axis of an ion beam generated by the ion implanter. In some non-limiting example embodiments, the surface texturing of the first and second side covers may comprise a plurality of serrations, and peaks and valleys of the serrations may be oriented perpendicular to the central axis of an ion beam generated by the ion implanter.

In some non-limiting example embodiments, the nose cover comprises a front portion and a top portion, where the surface texturing of the front portion and the top portion cover includes a plurality of serrations. Peaks and valleys of the serrations of the front portion may be oriented perpendicular to the central axis of an ion beam generated by the ion implanter, and peaks and valleys of the serrations of the top portion may be oriented parallel to the central axis of the ion beam.

In some non-limiting example embodiments, the platen portion is rotatable with respect to the base portion about an axis oriented perpendicular to a central axis of an ion beam generated by the ion implanter.

A platen is disclosed for use in an ion implanter. The platen may include a base portion, a platen portion coupled to the base portion, a front cover coupled to a front of the platen portion, the front cover comprising a surface texturing comprising a plurality of parallel serrations; first and second side covers coupled to first and second stationary shoulder portions of the base portion, the first and second side covers each comprising a curved portion and a side plate portion, the curved portions comprising a surface texturing comprising a plurality of parallel serrations, and a nose cover coupled to a front portion of the base portion. In some non-limiting example embodiments, the nose cover includes a front portion and a top portion oriented perpendicular with respect to each other. The front portion and the top portion each may include a surface texturing comprising a plurality of parallel serrations.

In some non-limiting example embodiments, the plurality of serrations of each of the front cover, the first and second side covers, and the nose cover comprise an apex angle of from 10-degrees to 120-degrees. Peaks and valleys of the serrations on the front cover can be oriented perpendicular to the central axis of an ion beam generated by the ion implanter. Peaks and valleys of the serrations on the first and second side covers can be oriented perpendicular to the central axis of an ion beam generated by the ion implanter. Peaks and valleys of the serrations on the top portion of the nose cover can be oriented parallel to the central axis of an ion beam generated by the ion implanter. Peaks and valleys of the serrations on the front portion of the nose cover can be oriented perpendicular to the central axis of an ion beam generated by the ion implanter.

An ion implanter is disclosed and may include an ion source, a process chamber in which a substrate is disposable, and a platen disposed within the ion implanter. The platen can include a base portion, a platen portion rotatably coupled to the base portion, a front cover coupled to a front of the platen portion, first and second side covers coupled to first and second stationary shoulder portions of the base portion, and a nose cover coupled to a front portion of the base portion. The front cover, the first and second side covers, and the nose cover, each may include a surface texturing. In some non-limiting example embodiments, the surface texturing comprises a plurality of serrations.

The surface texturing of the front cover comprises a plurality of serrations, and wherein peaks and valleys of the serrations can be oriented perpendicular to the central axis of an ion beam generated by the ion implanter. The surface texturing of the first and second side covers can include a plurality of serrations. Peaks and valleys of the serrations may be oriented perpendicular to the central axis of an ion beam generated by the ion implanter.

The nose cover can include a front portion and a top portion, where the surface texturing of the front portion and the top portion cover includes a plurality of serrations, where peaks and valleys of the serrations of the front portion are oriented perpendicular to the central axis of an ion beam generated by the ion implanter. Peaks and valleys of the serrations of the top portion can be oriented parallel to the central axis of the ion beam. In some non-limiting example embodiments, the platen portion is rotatable with respect to the base portion about an axis oriented perpendicular to a central axis of an ion beam generated by the ion implanter.

### BRIEF DESCRIPTION OF THE DRAWINGS

The accompanying drawings illustrate exemplary approaches of the disclosure, including the practical application of the principles thereof, as follows:

FIG. 1 illustrates a schematic diagram of a beamline processing apparatus according to embodiments of the present disclosure.

FIG. 2 is a side view of a non-limiting example embodiment of a rotatable platen.

FIGS. 3A-3C illustrate a portion of the schematic diagram of FIG. 1 showing the locations of ion beam induced depositions of surfaces within the process chamber.

FIGS. 4A-4C illustrate a portion of the schematic diagram of FIG. 1 showing the locations of ion beam induced depositions of surfaces within the process chamber.

FIGS. 5A-5C illustrate a portion of the schematic diagram of FIG. 1 showing the locations of ion beam induced depositions of surfaces within the process chamber.

FIG. 6 is an exploded isometric view of an example rotary platen apparatus including an example textured front cover, example textured side covers, and example textured nose cover in accordance with the disclosure.

FIG. 7 is an isometric view of an example side cover for use with the example rotary platen apparatus of FIG. 6.

FIG. 8 is a cross-section view of an example arrangement of serrations that can be used with the textured front cover, textured side covers, and textured nose cover of FIGS. 6 and 7.

FIG. 9 is a cross-section view of an example arrangement of serrations that can be used with the textured side covers of FIG. 6.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of "slices", or "near-sighted" cross-sectional views, omitting certain background lines otherwise visible in a "true" cross-sectional view, for illustrative clarity. Furthermore, for clarity, some reference numbers may be omitted in certain drawings.

### DETAILED DESCRIPTION

Methods, devices, and systems in accordance with the present disclosure will now be described more fully hereinafter with reference to the accompanying drawings, where various embodiments are shown. The methods, devices, and systems may be embodied in many different forms and are not to be construed as being limited to the embodiments set forth herein. Instead, these embodiments are provided so the disclosure will be thorough and complete, and will fully convey the scope of the methods to those skilled in the art.

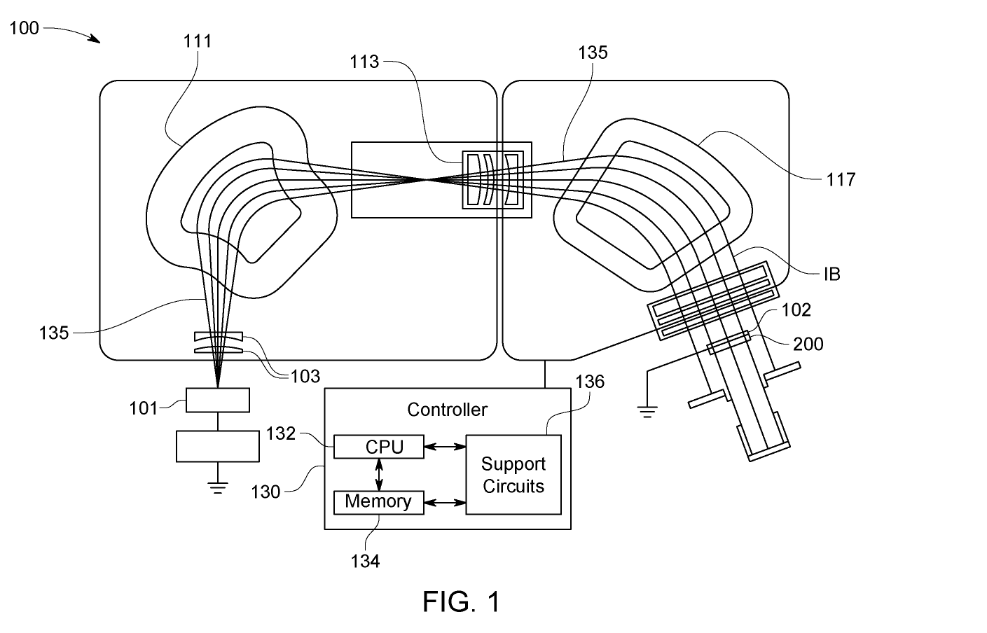

FIG. 1 illustrates a schematic diagram of an ion implanter 100. The ion implanter 100 may include an ion source 101 for generating ions. For example, the ion source 101 may provide an ion implant, such as the ion implant for introducing ion species into a substrate 102 to be processed. In non-limiting example embodiments, the substrate 102 is a semiconductor wafer.

The ion implanter 100 may also include a series of beam-line components. Examples of beam-line components may include extraction electrodes 103, a magnetic mass analyzer 111, a plurality of lenses 113, and a beam collimator 117. The ion implanter 100 may also include a rotary platen apparatus 200 for supporting a substrate 102 to be processed. The substrate 102 may be moved in one or more dimensions (e.g., translated, rotated, tilted) by the rotary platen apparatus 200. It is also contemplated that in some embodiments the ion implanter 100 may be configured to perform heated implantation processes to provide for improved control of implantation characteristics, such as the ion trajectory and implantation energy utilized to dope the substrate.

In operation, ions of the desired species, for example, dopant ions, are generated and extracted from the ion source 101. Thereafter, the extracted ions 135 travel in a beam-like state (IB”) along the beam-line components and may be implanted in the substrate 102. Similar to a series of optical lenses that manipulate a light beam, the beam-line components manipulate the extracted ions 135 along the ion beam. In such a manner, the extracted ions 135 are manipulated by the beam-line components while the extracted ions 135 are directed toward the substrate 102. It is contemplated that the ion implanter 100 may provide for improved mass selection to implant desired ions while reducing the probability of undesirable ions (impurities) being implanted in the substrate 102.

In some embodiments, the ion implanter 100 can be controlled by a processor-based system controller such as controller 130, which may include a programmable central processing unit (CPU) 132 that is operable with a memory 134 and a mass storage device, an input control unit, and a display unit (not shown), such as power supplies, clocks, cache, input/output (I/O) circuits, and the like, coupled to the various components of the ion implanter 100 to facilitate control of the substrate processing. The controller 130 also includes hardware for monitoring substrate processing through sensors in the ion implanter 100, including sensors monitoring the substrate position and sensors configured to receive feedback from and control a heating apparatus coupled to the ion implanter 100. Other sensors that measure system parameters such as substrate temperature and the like, may also provide information to the controller 130. Support circuits 136 may be coupled to the CPU 132 for supporting the processor in a conventional manner. Implantation and other processes are generally stored in the memory 134, typically as a software routine. The software routine may also be stored and/or executed by a second CPU (not shown) that is remotely located from the hardware being controlled by the CPU 132.

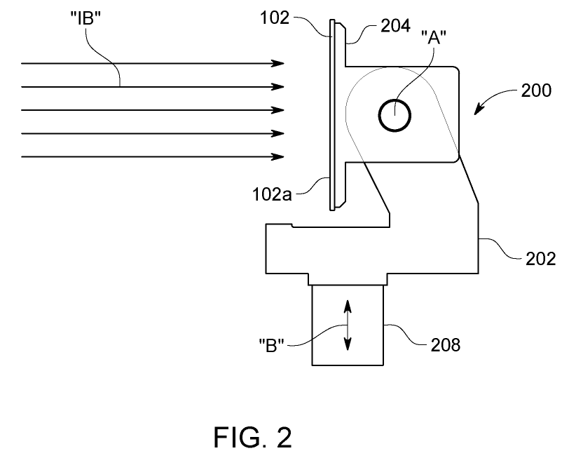

FIG. 2 shows a non-limiting example embodiment of a rotary platen apparatus 200 including a base portion 202, and a platen portion 204 rotatably mounted to the base portion 202 so that the platen portion 204 can rotate with respect to the base portion 202 about an axis “A”. A motor (not shown) can be coupled to or between the base portion 202 and the platen portion 204 to enable the platen and substrate 102 to be selectively rotated up to 90-degrees with respect to the base portion 202. This selective rotation enables the rotary platen apparatus 200 to present a first surface 102a of the substrate 102 to an incoming ion beam IB at any of a variety of angular positions between horizontal (i.e., the platen portion 204 and substrate surface 102 are parallel to the ion beam IB) and vertical (i.e., the platen portion 204 and the first surface 102a of the substrate 102 are perpendicular to the ion beam IB). The base portion 202 can also be coupled to a scanning arm 208 so that the base portion 202 and platen portion 204 can be moved perpendicular to the direction of the ion beam IB in the direction of arrow “B”, which, as will be described in greater detail later allows the base portion 202 and platen portion 204 (along with the substrate 102) to be selectively scanned through the ion beam IB. By enabling the platen portion 204 to be selectively angled with respect to the base portion 202, the substrate 102 can be impinged by the ion beam IB at any of a variety of desired angles while the substrate 102 is being scanned through the ion beam IB in the direction of arrow “B”.

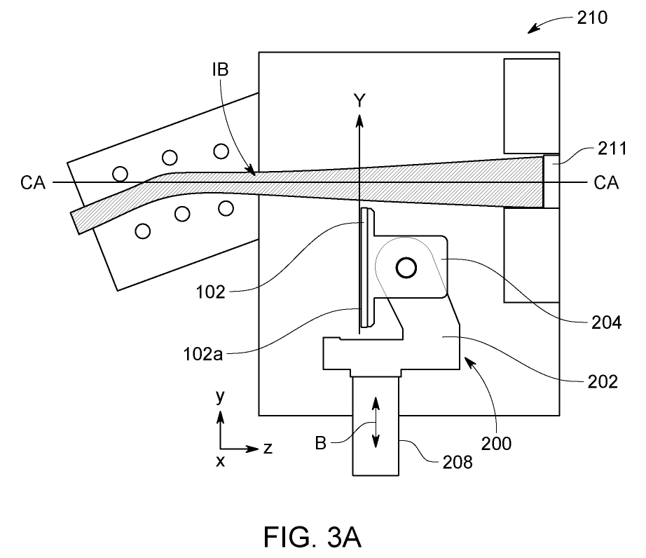

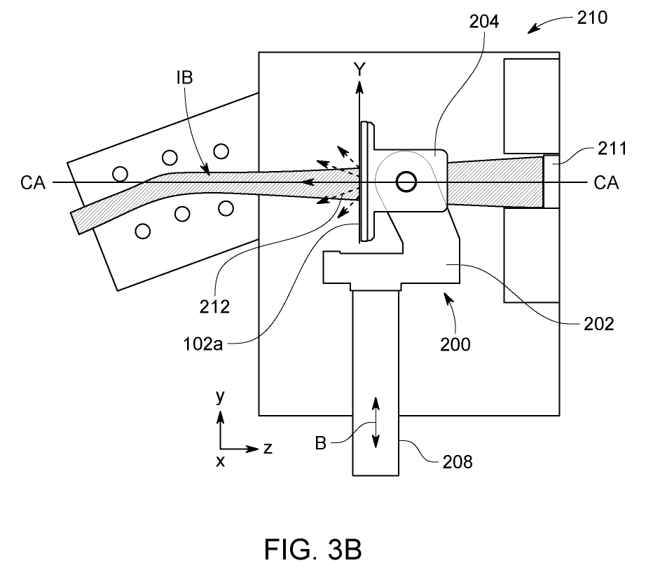

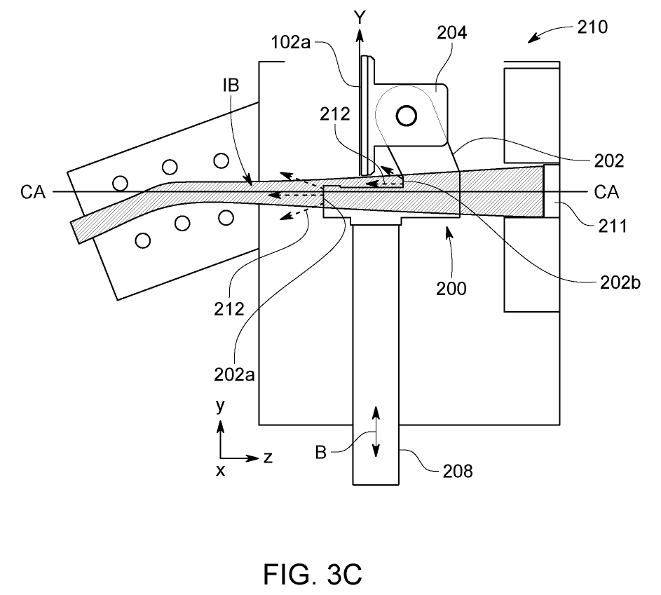

FIGS. 3A – 5C are schematic illustrations of an example low-energy ion beam IB (e.g., 100 eV to 10 keV energy range) impinging various surfaces in an example process chamber 210 during ion implant processes. As previously mentioned, in implant processes, films can be formed on these surfaces when those surfaces are subject to direct impingement by the ion beam IB. Flaking films can cause particle issues on the substrate that lead to device yield loss. As will be described in greater detail, when a substrate 102 is mounted on a rotary platen apparatus 200 and then scanned through the ion beam IB, various portions of the process chamber 210 and the rotary platen apparatus 200 can be subject to direct impingement by the ion beam IB. As will be appreciated, this can change depending on the orientation angle of the substrate 102 with respect to the ion beam IB.

FIGS. 3A – 3C show an example of several stages of a “0-degree tilt implant”. In this embodiment the platen portion 204 of the rotary platen apparatus 200 is rotated with respect to the base portion 202 about axis “A” so that a first surface 102a the substrate 102 is oriented parallel to the vertical axis “Y” and perpendicular to the central axis “CA” of the ion beam IB. It will be appreciated that under 0-degree tilt implants, most sputtered atoms are generated at low energies.

In the position shown in FIG. 3A, the rotary platen apparatus 200 is positioned below the ion beam IB. As can be seen, the ion beam IB directly impinges a dose cup 211 associated with the process chamber 210. In the position shown in FIG. 3B, the scanning arm 208 moves the rotary platen apparatus 200 vertically along the vertical axis “Y” so that the substrate 102 is directly impinged by the ion beam IB. In this position that low energy sputter materials 212 are reflected and/or ejected from the first surface 102a of the substrate 102 back toward the incoming ion beam IB and surfaces of the process chamber 210 adjacent thereto. In the position shown in FIG. 3C, the scanning arm 208 has moved the rotary platen apparatus 200 vertically along the vertical axis “Y” so that the substrate 102 is positioned beyond the ion beam IB. In this position the ion beam IB directly impinges first and second surfaces 202a, 202b of the base portion 202 of the rotary platen apparatus 200. As a result of this impingement, low energy sputter materials are ejected from the first and second surfaces 202a, 202b of the base portion 202 of the rotary platen apparatus 200, back toward the incoming ion beam and surfaces adjacent there too.

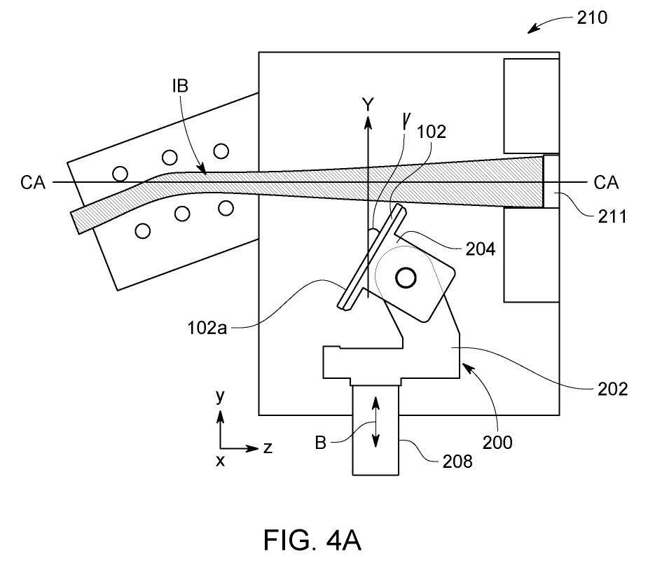

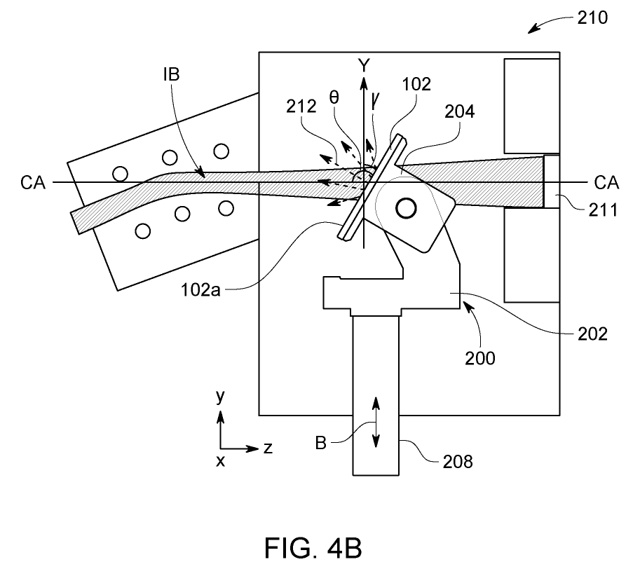

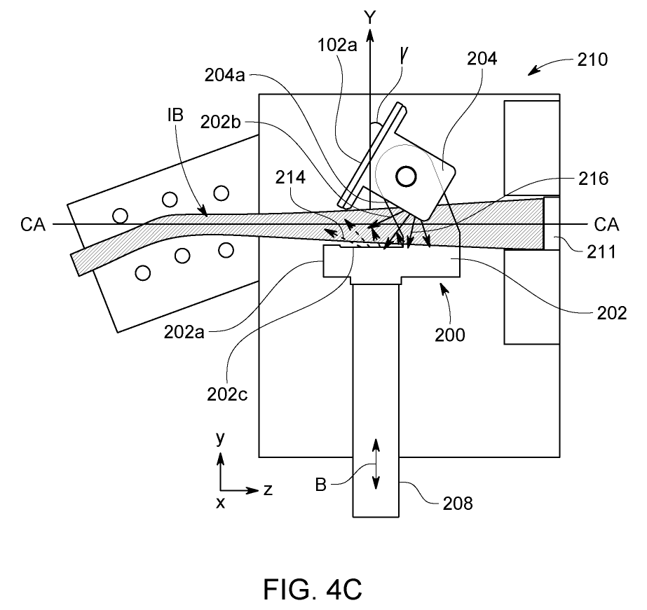

FIGS. 4A – 4C show an example of several stages of a “30-degree tilt implant”. In this embodiment the platen portion 204 of the rotary platen apparatus 200 is rotated with respect to the base portion 202 about axis “A” so that a first surface 102a the substrate 102 is oriented at an angle γ with respect to the vertical axis “Y” and an angle θ (FIG. 4B) with respect to the central axis “CA” of the ion beam IB. In the illustrated embodiment angle γ is 30-degrees, and angle θ is 120-degrees. It will be appreciated that under 30-degree tilt implants, energetic particles and secondary sputter materials are expected to be produced.

In the position shown in FIG. 4A, the rotary platen apparatus 200 is positioned below the ion beam IB. The platen portion 204 and the substrate 102 are tilted with respect to the base portion 202 such that the first surface 102a of the substrate 102 is oriented at a 30-degree angle (γ) with respect to the vertical axis “Y”. In this position, the ion beam IB directly impinges the dose cup 211. In the position shown in FIG. 4B, the scanning arm 208 has moved the rotary platen apparatus 200 vertically along the vertical axis “Y” so that the substrate 102 is directly impinged by the ion beam IB. In this position low energy sputter materials 212 are reflected and/or ejected from the first surface 102a of the substrate 102 back, upward, and downward, toward the incoming ion beam IB as well as surfaces of the process chamber 210 adjacent thereto. In the position shown in FIG. 4C, the scanning arm 208 has continued to move the platen portion 204 and the substrate 102 vertically along the “Y” axis such that the substrate 102 is positioned beyond the ion beam IB. In this position the ion beam IB directly impinges second and third surfaces 202b, 202c of the base portion 202 of the rotary platen apparatus 200, as well as first surface 204a of the platen portion 204. As a result of this impingement, energetic particles 216 are reflected and/or ejected from the first surface 204a of the platen portion 204. These energetic particles 216 can impact the third surface 202c of the base portion 202, resulting in secondary sputter materials 214 being generated from the third surface 202c and traveling toward various surfaces within the process chamber 210. These secondary sputter materials 214 and energetic particles 216 travel toward various surfaces within the process chamber 210.

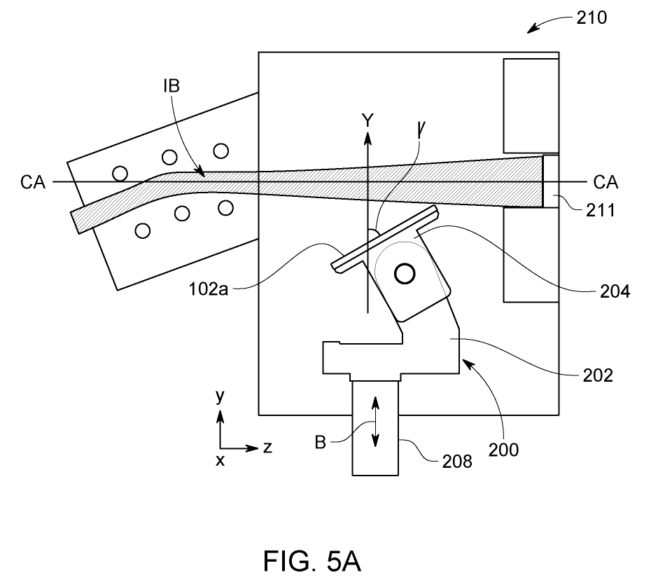

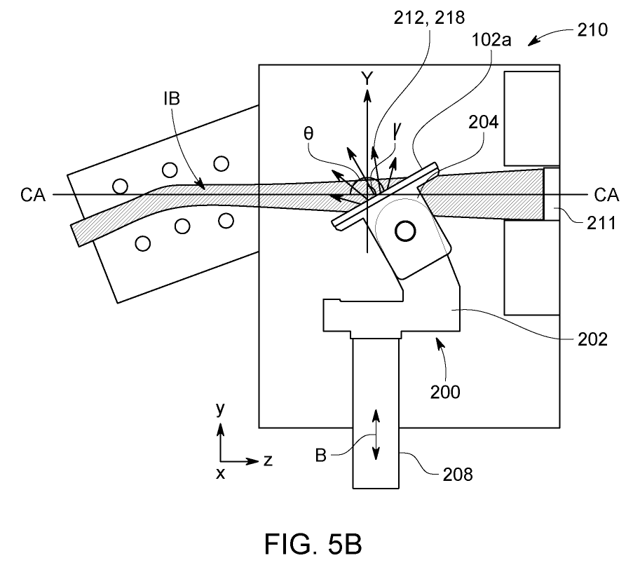

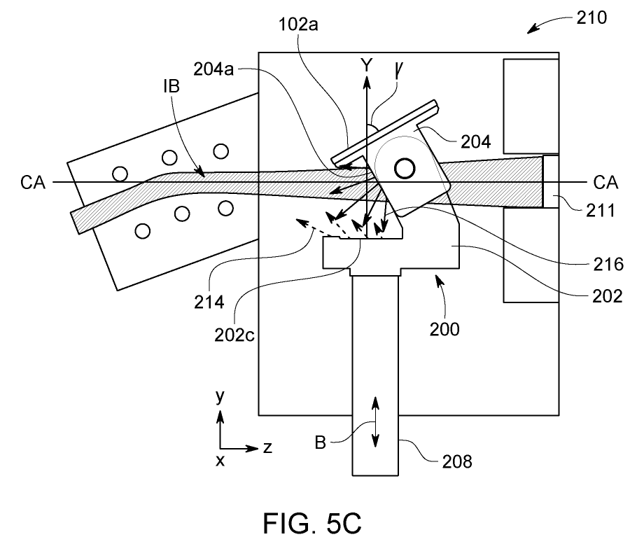

FIGS. 5A – 5C show an example of several stages of a “60-degree tilt implant”. In this embodiment the platen portion 204 of the rotary platen apparatus 200 is rotated with respect to the base portion 202 about axis “A” so that a first surface 102a the substrate 102 is oriented at an angle γ with respect to the vertical axis “Y”, and an angle θ (FIG. 5B) with respect to the central axis “CA” of the ion beam IB. In the illustrated embodiment angle γ is 60-degrees, and angle θ is 150-degrees. It will be appreciated that under 60-degree tilt implants, energetic particles and secondary sputter materials are expected to be produced.

In the position shown in FIG. 5A, the rotary platen apparatus 200 is positioned below the ion beam IB. The platen portion 204 and the substrate 102 are tilted with respect to the base portion 202 such that the first surface 102a of the substrate 102 is oriented at a 60-degree angle (γ) with respect to the vertical axis “Y”. In this position, the ion beam IB directly impinges the dose cup 211. In the position shown in FIG. 5B, the scanning arm 208 has moved the rotary platen apparatus 200 vertically along the vertical axis “Y” so that the substrate 102 is directly impinged by the ion beam IB. In this position low and high energy sputter materials 212, 218 are reflected and/or ejected from the first surface 102a of the substrate 102 back, and upward toward the incoming ion beam IB as well as surfaces of the process chamber 210 adjacent thereto. In the position shown in FIG. 5C, the scanning arm 208 has continued to move the platen portion 204 and the substrate 102 vertically along the vertical axis “Y” such that the substrate 102 is positioned beyond the ion beam IB. In this position the ion beam IB directly impinges the first surface 204a of the platen portion 204. As a result of this impingement, energetic particles 216 are reflected and/or ejected from the first surface 204a of the platen portion 204. These energetic particles 216 can impact the third surface 202c of the base portion 202, resulting in secondary sputter materials 214 being generated from the third surface 202c, and traveling toward various surfaces within the process chamber 210.

As previously mentioned, without remediation, films can be formed on the surfaces of the rotary platen apparatus 200 and process chamber 210 as a result of the low energy sputter materials 212, energetic particles 216, and secondary sputter materials 214. To alleviate this problem, surfaces of the rotary platen apparatus 200 can be adapted to prevent the accumulation of films thereon. In some non-limiting example embodiments, selected surfaces of the rotary platen apparatus 200 can be textured to interrupt otherwise large, smooth, surface areas and so prevent films from accumulating. In some embodiments the surface texturing can be provided on plate members that can be coupled to the selected surfaces of the rotary platen apparatus 200. In some embodiments the texturing can comprise a series of serrations.

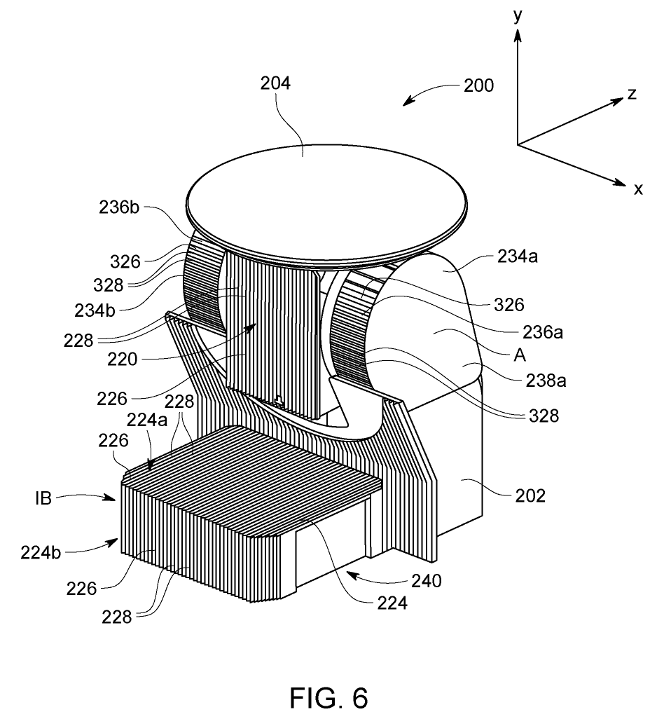

FIG. 6 illustrates an example rotary platen apparatus 200 including base portion 202 and platen portion 204. As previously mentioned, the platen portion 204 is rotatable with respect to the base portion 202 about axis “A” to enable tilted implants to be performed on a substrate (not shown) mounted on the platen portion 204. In the illustrated embodiment axis “A” is oriented parallel to the X-axis (which is perpendicular to the incoming ion beam IB) and is oriented perpendicular to the vertical Y-axis. The rotary platen apparatus 200 may also include features that reduce the generation of particles, reduce the generation of secondary sputter materials, or prevent such particles and sputter materials from being released into the process chamber 201 where they can impact the substrate 102 or other surfaces. In the illustrated embodiment these features may be implemented in a plurality of covers that can be fit on or over different portions of the rotary platen apparatus 200. Specifically, a front cover 220, first and second side covers 234a, 234b, and a nose cover 224 can be provided to cover respective portions of the rotary platen apparatus 200.

The front cover 220 can be coupled to a front of the platen portion 204 of the rotary platen apparatus 200. Thus positioned, the front cover 220 may be directly impinged by the ion beam IB during implant operations (see, e.g., FIGS. 3C, 4C and 5C). As can be seen, the front cover 220 comprises a generally flat, rectangular plate having a textured surface 226. In the illustrated embodiment the textured surface 226 comprises a plurality of parallel serrations 228. In some embodiments the plurality of serrations 228 can comprise a plurality of alternating peaks 230 and valleys 232 (FIG. 8) that when installed on the rotary platen apparatus 200 are oriented parallel to the Y-axis when the platen portion 204 is oriented parallel to the ion beam IB (i.e., the platen portion is oriented in the X-Z plane).

As will be appreciated, since the front cover 220 is coupled to the platen portion 204 of the rotatable platen apparatus 200, its orientation with respect to the ion beam IB will change as the tilt angle of the platen portion 204 changes. Thus arranged, the front cover 220 directs the energetic particles 216 produced during ion implant operations toward the valleys 232 of the serrations 228 and also toward a top portion 224a of the nose cover 224.

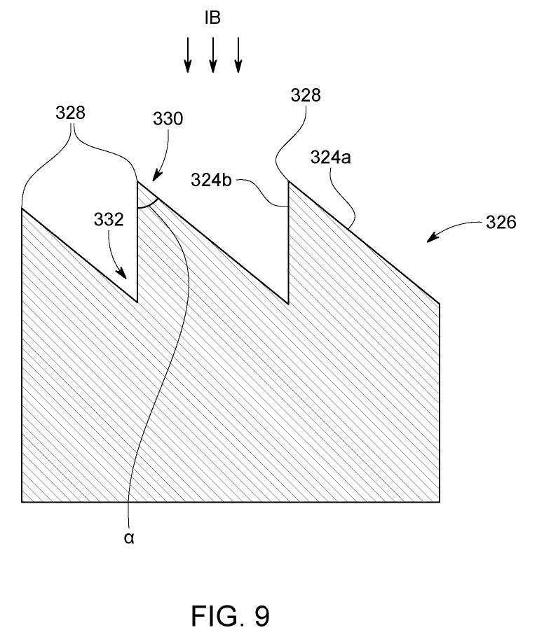

The first and second side covers 234a, 234b can be coupled to first and second stationary shoulder portions (not shown) of the rotary platen apparatus 200. Thus positioned, the first and second side covers 234a, 234b may be directly impinged by the ion beam IB during high tilt ion implant operations (see, e.g., FIG. 5C). As can be seen, the first and second side covers 234a, 234b comprise respective curved portions 236a, 236b that are curved about axis A, which is the axis about which the platen portion 204 rotates during operation, and which is parallel to the X-axis. The first and second side covers 234a, 234b may also comprise respective side plate portions 238a, 238b. The curved portions 236a, 236b can generally conform to the associated stationary shoulder portion (not shown) of the rotary platen apparatus 200. The curved portions 236a, 236b of the first and second side covers 234a, 234b each has a textured surface 326, which in the illustrated embodiment comprises a plurality of serrations 328 (see FIG. 9). In the illustrated embodiment, the plurality of parallel serrations 328 can comprise a plurality of alternating peaks 330 and valleys 332 (FIG. 9) that, when installed on the rotary platen apparatus 200 are oriented parallel to the X-axis and perpendicular to the Z-axis (i.e., perpendicular to the ion beam IB). As will be appreciated, since the first and second side covers 234a, 234b are coupled to the base portion 202 of the rotatable platen apparatus 200 (via the shoulder portions), their orientation with respect to the ion beam IB will not change as the tilt angle of the platen portion 204 changes. Thus arranged, the first and second side covers can prevent film deposition, which can lead to flaking, caused by impingement of the ion beam IB and sputter materials 212.

The nose cover 224 can be coupled to a front portion 240 of the base portion 202 of the rotary platen apparatus 200. Thus positioned, the nose cover 224 may be directly impinged by the ion beam IB during low tilt ion implant operations (see, e.g., FIG. 3C). The nose cover 224 can also be impacted by energetic particles 216 during medium and high tilt applications (see, e.g., FIG. 4C, 5C).

The nose cover 224 can comprise a top portion 224a, and a front portion 224b oriented generally perpendicular to the top portion 224a. When installed, the front portion 224b may be oriented generally vertically (i.e., in the X-Y plane), while the top portion 224a may be oriented generally horizontal (i.e., in the X-Z plane). As can be seen, the top and front portions 224a, 224b each comprise a generally flat, rectangular plate element having a textured surface 226. In the illustrated embodiment the textured surfaces 226 of the top and front portions 224a, 224b comprises a plurality of serrations 228 formed by alternating peaks 230 and valleys 232 (see FIG. 8).

When the nose cover 224 is installed on the rotary platen apparatus 200, the serrations 228 of the top portion 224a may be oriented parallel to the Z-axis (i.e., parallel to the ion beam IB), while the serrations 228 of the front portion 224b may be oriented parallel to the Y-axis (i.e, perpendicular to the ion beam IB). As will be appreciated, since the nose cover 224 is coupled to the base portion 202 of the rotatable platen apparatus 200, its orientation with respect to the ion beam IB will not change as the tilt angle of the platen portion 204 changes. Thus arranged, the serrations 228 of the top portion 224a can prevent film deposition and flaking caused by impingement by sputtered materials 214. The serrations 228 on the front portion 224b can prevent deposition/flaking due to direct impact by the ion beam IB.

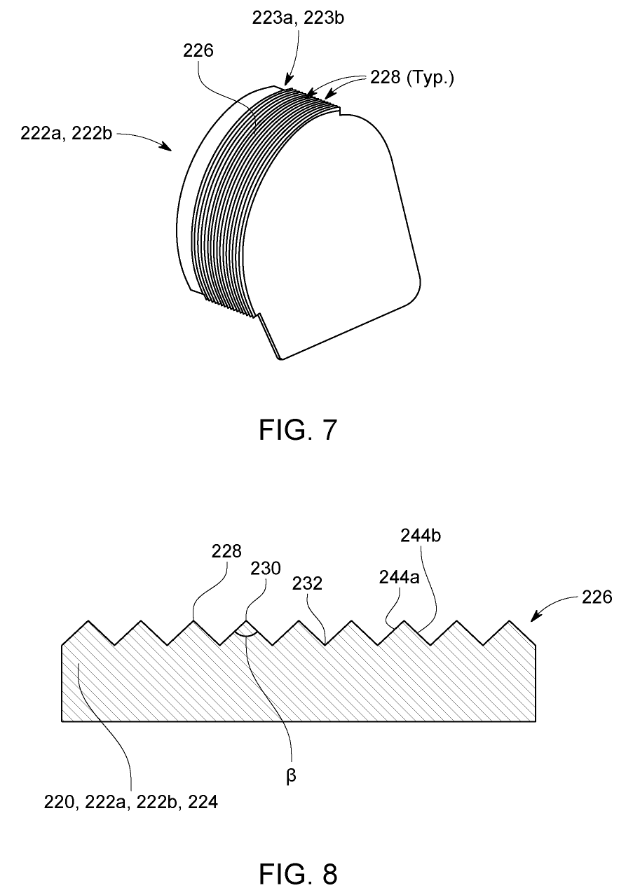

FIG. 7 shows an alternative configuration of a side cover 222a, 222b in which the curved portions 223a, 223b include a textured surface 226 that includes plurality of serrations 228 having a plurality of alternating peaks 230 and valleys 232 (see FIG. 8) that, when installed on associated shoulder portions of the rotary platen apparatus 200, follow the curvature of the curved portions 223a, 223b. That is, when viewed along the Z-axis, the plurality of parallel serrations 228 appear to be parallel to the Y-axis. This arrangement can be used if the platen portion 204 is tilted along the Y-axis.

FIG. 8 illustrates a cross-section of a non-limiting example of a surface texturing arrangement that can be applied to the front cover 220, the FIG. 7 embodiment of the side covers 222a, 222b, and the nose cover 224 of the rotary platen apparatus 200. In the illustrated embodiments the textured surface 226 comprises a plurality of parallel serrations 228. The serrations 228 can each include first and second angled faces 244a, 244b that form a peak angle β. In some embodiments this peak angle β can be from about 10 degrees to about 120 degrees, and in one non-limiting example embodiment can be about 60-degrees. In some non-limiting example embodiments, the serrations 228 can be from about 100 to about 10,000 micrometers in height/depth. In one non-limiting example embodiment, the serrations 228 can be from about 1-6 mm in height/depth. As will be appreciated, the serrations 228 can be created by any appropriate technology, such as machining, sanding, grinding, chemical etching, molding, pressing, or the like.

FIG. 9 shows an example of a surface texturing arrangement that can be applied to the embodiment of the side covers 222a, 222b shown in FIG. 6. In the illustrated embodiments the textured surface 326 comprises a plurality of parallel serrations 328 comprising a plurality of alternating peaks 330 and valleys 332. The serrations 328 can each include first and second angled faces 324a, 324b that form a peak angle α. In some embodiments this peak angle α can be from about 5 degrees to about 60 degrees, and in one non-limiting example embodiment can be about 25 degrees.

Compared to the embodiment of FIG. 8, in which the serrations 228 are symmetrical (i.e., they have first and second angled faces 244a, 244b that are angled by the same amount with respect to the textured surface 226), the serrations 328 of FIG. 9 are asymmetric (i.e., the angled faces 324a, 324b form substantially different angles with respect to the textured surface 326), resulting in a “saw tooth” configuration. In the non-limiting illustrated embodiment, the first angled face 324a is oriented at an oblique angle with respect to the ion beam IB, while the second angled face 324b is oriented parallel to the ion beam IB. It will be appreciated, however, that the first and second angled faces 324a, 324b can be configured so that they are both oriented at an oblique angle with respect to the ion beam IB.

It will further be appreciated that in some embodiments the first and second angled faces 324a, 324b of adjacent serrations 328 can be configured differently. That is, the first and/or second angled faces 324a, 324b of a first one of the plurality of serrations 328 can be configured at different angles compared to the first and/or second angled faces 324a, 324b of a second one of the plurality of serrations 328. In some embodiments such geometric changes in adjacent serrations 328 can be made progressive about the curved portion 236a, 236b, so that each of the serrations 328 assumes a desired orientation with respect to the ion beam IB.

In some non-limiting example embodiments, the serrations 328 can be from about 100 to about 10,000 micrometers in height/depth. In one non-limiting example embodiment, the serrations 328 can be from about 1-6 mm in height/depth. As will be appreciated, the serrations 328 can be created by any appropriate technology, such as machining, sanding, grinding, chemical etching, molding, pressing, or the like.

It will be appreciated that although the textured surfaces 226 are disclosed as being serrations, that such is not limiting and other types of surface texturing are contemplated. For example, the surface texturing embodiments disclosed in U.S. Provisional Patent Application No. 63/742,942, filed Jan. 8, 2025, which is incorporated by reference herein, can be implemented in or on one or more of the serrated surfaces disclosed in the present application.

For the sake of convenience and clarity, terms such as “top,” “bottom,” “upper,” “lower,” “vertical,” “horizontal,” “lateral,” and “longitudinal” will be understood as describing the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporating the recited features.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

While certain embodiments of the disclosure have been described herein, the disclosure is not limited thereto, as the disclosure is as broad in scope as the art will allow and

the specification may be read likewise. Therefore, the above description is not to be construed as limiting. Instead, the above description is merely as exemplifications of particular embodiments. Those skilled in the art will envision other modifications within the scope and spirit of the claims appended hereto.

What is claimed is:

1. A platen for use in an ion implanter, the platen comprising:
a base portion,
a platen portion rotatably coupled to the base portion,
a front cover coupled to a front of the platen portion,
first and second side covers coupled to first and second stationary shoulder portions of the base portion, and
a nose cover coupled to a front portion of the base portion,
wherein the front cover, the first and second side covers, and the nose cover, each comprise a surface texturing.

2. The platen of claim 1, wherein the surface texturing comprises a plurality of serrations.

3. The platen of claim 1, wherein the surface texturing of the front cover comprises a plurality of serrations, and wherein peaks and valleys of the serrations are oriented perpendicular to a rotational axis of the platen portion.

4. The platen of claim 1, wherein the surface texturing of the first and second side covers comprise a plurality of serrations, and wherein peaks and valleys of the plurality of serrations are oriented parallel to a rotational axis of the platen portion.

5. The platen of claim 1, wherein the nose cover comprises a front portion and a top portion, wherein the surface texturing of the front portion and the top portion cover comprises a plurality of serrations, wherein peaks and valleys of the serrations of the front portion are oriented perpendicular to a rotational axis of the platen portion, and wherein peaks and valleys of the serrations of the top portion are oriented perpendicular to the peaks and valleys of the serrations of the front portion.

6. The platen of claim 1, wherein the platen portion is rotatable with respect to the base portion about an axis oriented perpendicular to a central axis of an ion beam generated by the ion implanter.

7. A platen for use in an ion implanter, the platen comprising:
a base portion,
a platen portion coupled to the base portion,
a front cover coupled to a front of the platen portion, the front cover comprising a surface texturing comprising a plurality of parallel serrations;
first and second side covers coupled to first and second stationary shoulder portions of the base portion, the first and second side covers each comprising a curved portion and a side plate portion, the curved portions comprising a surface texturing comprising a plurality of parallel serrations; and
a nose cover coupled to a front portion of the base portion, the nose cover comprising a front portion and a top portion oriented perpendicular with respect to each other, the front portion and the top portion each comprising a surface texturing comprising a plurality of parallel serrations.

8. The platen of claim 7, wherein the plurality of parallel serrations of each of the front cover, the first and second side covers, and the nose cover comprise an apex angle of from 10-degrees to 120-degrees.

9. The platen of claim 7, wherein peaks and valleys of the plurality of parallel serrations on the front cover are oriented perpendicular to a rotational axis of the platen portion.

10. The platen of claim 7, wherein peaks and valleys of the plurality of parallel serrations on the first and second side covers are oriented parallel to a rotational axis of the platen portion.

11. The platen of claim 7, wherein peaks and valleys of the plurality of parallel serrations on the top portion of the nose cover are oriented perpendicular to a rotational axis of the platen portion.

12. The platen of claim 11, wherein peaks and valleys of the serrations on the front portion of the nose cover are oriented perpendicular to a rotational axis of the platen portion, and are oriented perpendicular to the peaks and valleys of the serrations on the top portion of the nose cover.

13. An ion implanter, comprising
an ion source;
a process chamber in which a substrate is disposable; and
a platen disposed within the ion implanter, the platen comprising:
a base portion,
a platen portion rotatably coupled to the base portion,
a front cover coupled to a front of the platen portion,
first and second side covers coupled to first and second stationary shoulder portions of the base portion, and
a nose cover coupled to a front portion of the base portion,
wherein the front cover, the first and second side covers, and the nose cover, each comprise a surface texturing.

14. The ion implanter of claim 13, wherein the surface texturing comprises a plurality of serrations.

15. The ion implanter of claim 13, wherein the surface texturing of the front cover comprises a plurality of serrations, and wherein peaks and valleys of the serrations are oriented perpendicular to a rotational axis of the platen portion.

16. The ion implanter of claim 13, wherein the surface texturing of the first and second side covers comprise a plurality of serrations, and wherein peaks and valleys of the serrations are oriented parallel to a rotational axis of the platen portion.

17. The ion implanter of claim 13, wherein the nose cover comprises a front portion and a top portion, wherein the surface texturing of the front portion and the top portion cover comprises a plurality of serrations, wherein peaks and valleys of the serrations of the front portion are oriented perpendicular to a rotational axis of the platen portion, and wherein peaks and valleys of the serrations of the top portion are oriented perpendicular to the peaks and valleys of the serrations of the front portion.

18. The ion implanter of claim 13, wherein the platen portion is rotatable with respect to the base portion about an axis oriented perpendicular to a central axis of an ion beam generated by the ion implanter.
